(19) United States
(12) Patent Application Publication
(10) Pub. No.: US 2009/0125159 A1
(43) Pub. Date: May 14, 2009

(54) HEAT DISSIPATING SYSTEM

(75) Inventors: Chi-Chen SHEN, Taoyuan Hsien (TW); Lee-Long CHEN, Taoyuan Hsien (TW)

Correspondence Address: Muncy, Geissler, Olds & Lowe, PLLC, P.O. BOX 1364, FAIRFAX, VA, 22038-1364, US

(73) Assignee: DELTA ELECTRONICS, INC, Kuei San (TW)

(21) Appl. No.: 12/209,756

(22) Filed: Sep. 12, 2008

(30) Foreign Application Priority Data
Nov. 9, 2007 (TW) 096142450

(51) Int. Cl. H05K 7/20; G08B 23/00; G05D 23/00

(52) U.S. Cl. 700/300; 361/695; 340/500

(57) ABSTRACT

A heat dissipating system includes a fan set and a monitoring module. The fan set has at least one fan. The monitoring module has at least one sensing unit, a controlling unit and a setting unit. The setting unit sets a plurality of parameter values. The controlling unit controls a rotation speed of the fan according to the parameter values and/or at least one measured value sensed by the sensing unit.

### CROSS REFERENCE TO RELATED APPLICATIONS

This Non-provisional application claims priority under 35 U.S.C. §119(a) on Patent Application No(s). 096142450 filed in Taiwan, Republic of China on Nov. 9, 2007, the entire contents of which are hereby incorporated by reference.

### BACKGROUND OF THE INVENTION

1. Field of Invention

The present invention relates to a heat dissipating system and in particular to a heat dissipating system having a monitoring module.

2. Related Art

As the electronic product is rapidly developed and has high performance, high frequency transmission and thin thickness, the temperature of the electronic product is increased so that the electronic product may be unstable and thus influence the reliability and the lifetime of the product. Therefore, the heat dissipation has become an important subject in the electronic product. A fan is frequently used to serve as a heat-dissipating device for lowering the temperature of the electronic product. In order to enhance the heat dissipating efficiency, a plurality of fans can be combined to form a fan set.

The currently available heat dissipating system having a fan set usually has very simple functions. For example, when the environment temperature rises to a predetermined temperature, the fan set is enabled to operate at the full speed, and the function of controlling the rotation speed in a multi-stage manner is not provided. In this case, when the heat dissipating requirement is not high, the energy is wasted. In addition, the user also cannot set parameter values in the conventional heat dissipating system to control the rotation speed so that the rotation speed cannot be intelligently adjusted. In addition, when the heat dissipating system has a plurality of fan sets, how to individually control the fan sets is a problem to be solved.

### SUMMARY OF THE INVENTION

In view of the foregoing, the present invention is to provide a heat dissipating system capable of individually controlling each fan set and to allow a user to set parameter values to achieve the functions of controlling the rotation speed in a multi-stage manner and adjusting the rotation speed by an intelligent manner.

To achieve the above, the present invention discloses a heat dissipating system including a fan set and a monitoring module. The fan set has at least one fan, and the monitoring module has at least one sensing unit, a controlling unit and a setting unit. The setting unit sets a plurality of parameter values. The controlling unit controls a rotation speed of the fan according to the parameter values and/or at least one measured value sensed by the sensing unit.

In addition, the present invention also discloses a heat dissipating system including a plurality of fan sets and a plurality of monitoring modules. Each of the fan sets includes at least one fan. The monitoring modules respectively control rotation speeds of the fans of the fan sets. Each of the monitoring modules has an identification code, at least one sensing unit, a controlling unit and a setting unit. The setting unit sets a plurality of parameter values. The controlling unit controls the rotation speed of the corresponding fan set according to the parameter values and/or at least one measured value sensed by the sensing unit.

As mentioned above, the heat dissipating system of the present invention can set the parameter values via the setting unit of the monitoring module, and control the rotation speeds of the fans via the controlling unit according to the parameter values and/or the measured value sensed by the sensing unit. For example, the rotation speed is increased when the temperature rises, and the rotation speed is decreased when the temperature falls so that the rotation speed can be intelligently adjusted in a multi-stage manner. In addition, when the heat dissipating system has many fan sets and monitoring modules, each monitoring module has an identification code to be identified so that the individual control can be achieved. Compared with the prior art, the present invention allows the user to set the parameter values so that the function of intelligently adjusting the rotation speed in the multi-stage manner can be achieved, the heat dissipating efficiency and the working performance can be enhanced, and each of the fan sets can be individually controlled.

### BRIEF DESCRIPTION OF THE DRAWINGS

The present invention will become more fully understood from the subsequent detailed description and accompanying drawings, which are given by way of illustration only, and thus are not limitative of the present invention, and wherein:

FIG. 1 is a block diagram showing a heat dissipating system according to a first embodiment of the present invention;

FIG. 2 is another block diagram showing a heat dissipating system according to a second embodiment of the present invention;

FIG. 3 is a block diagram showing the heat dissipating system having a monitor connection module according to the second embodiment of the present invention; and

FIG. 4 is a block diagram showing a heat dissipating system according to a third embodiment of the present invention.

### DETAILED DESCRIPTION OF THE INVENTION

The present invention will be apparent from the following detailed description, which proceeds with reference to the accompanying drawings, wherein the same references relate to the same elements.

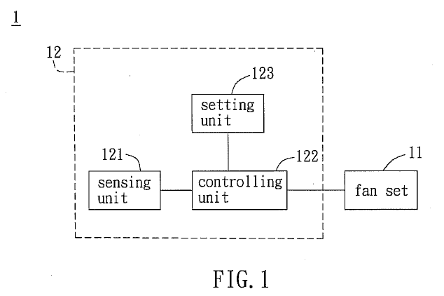

Referring to FIG. 1, a heat dissipating system. 1 according to a first embodiment of the present invention includes a fan set 11 and a monitoring module 12. The fan set 11 has at least one fan. In this embodiment, for example, the fan set 11 is a 3×3 fan set. That is, nine fans are installed in the 3×3 fan set. The user can install the fans in the fan set 11 according to the requirement.

The monitoring module 12 has at least one sensing unit 121, a controlling unit 122 and a setting unit 123. The number of the sensing unit(s) 121 can be changed according to the requirement. For example, if all fans of the fan set 11 are to be controlled uniformly, one sensing unit 121 is required. If all fans of the fan set 11 have to be individually controlled, multiple sensing units 121 respectively corresponding to the fans of the fan set 11 must be provided. The sensing unit 121 can include a temperature sensor, a humidity sensor, a temperature-humidity sensor or a rotation speed sensor.

The setting unit 123 sets a plurality of parameter values, which includes a temperature value, a humidity value, a temperature-humidity value or a rotation speed value. The controlling unit 122 controls the rotation speed of the fan according to the parameter values and/or at least one measured value sensed by the sensing unit 121. The measured value can be a temperature value, a humidity value, a temperature-humidity value or a rotation speed value. For example, after the user has set the highest temperature, the lowest temperature, the highest rotation speed and the lowest rotation speed, the controlling unit 122 controls the rotation speed according to the highest temperature, the lowest temperature, the highest rotation speed, the lowest rotation speed and the measured value (such as the temperature value sensed by the sensing unit 121, and the sensing unit 121 is the temperature sensor). The controlling unit 122 determines the rotation speed according to a look-up-table or a calculation of a formula. The parameter values and the measured values are described for the illustrative purpose and do not intend to limit the present invention. For example, it is also possible to control the rotation speed according to the humidity parameter value or other parameter values.

In addition, when the sensing unit 121 is a rotation speed sensor, it may be electrically connected with the fan of the fan set 11, and senses the rotation speed of the fan to output a rotation speed value, and the controlling unit 122 adjusts the rotation speed of the fan according to the rotation speed value. The actual rotation speed value can be fed back to the controlling unit 122 through the rotation speed sensor so that the feedback control can be performed.

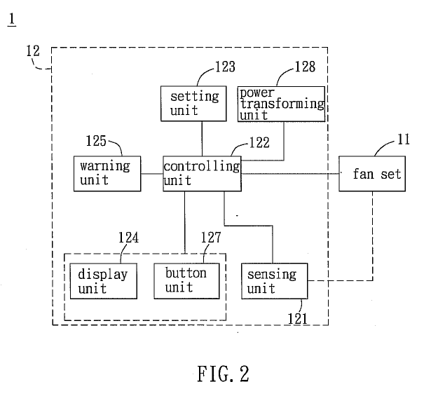

Referring to FIG. 2, the monitoring module 12 according to a second embodiment of the present invention further includes an operation interface having a display unit 124 and a button unit 127. The user can set various parameter values in the setting unit 123 via the input of the button unit 127 and the demonstration of the display unit 124. The button unit 127 may include a plurality of buttons. In addition, the setting unit 123 enables the user to set the parameter values in an intelligent manner via, for example, up and down buttons instead of digit buttons.

The display unit 124 demonstrates at least one information data in a cyclic manner. The information data may include a measured value and/or a parameter value. The display unit 124 can demonstrate the information data by changing the unit of the information data, such as the temperature value using the centigrade unit or the Fahrenheit unit, and the user can select the unit through the setting unit 123. In addition, when the monitoring module 12 is enabled, the display unit 124 can demonstrate a starting status scenario, which can provide important messages, such as the firmware version, the number of the fans and the number of the controlling unit(s) 122.

The monitoring module 12 further has a warning unit 125. When the measured value sensed by the sensing unit 121 exceeds a preset value, the warning unit 125 outputs a warning signal such as a warning voice, a warning text, a warning image or a warning flash. The warning unit 125 may be a speaker or a buzzer, for example. When the temperature value exceeds the maximum, a coil may be magnetized and the warning unit 125 is turned on to output the warning voice. The above-mentioned operations of the warning unit 125 are only for the illustrative purpose without restricting the scope of the present invention. In addition, the warning text, image and flash can also be demonstrated by the display unit 124.

In addition, the intelligent control of the controlling unit 122 can increase the rotation speeds of other fans when at least one of the fans fails so that the predetermined heat dissipating efficiency can be maintained. The rotation speeds can be increased by dividing the sum of the rotation speeds of all the fans by the number of the residual fans.

In addition, the monitoring module 12 further has a power transforming unit 128, which can receive an AC power input and transform the AC power input into a DC power output. In this embodiment, the DC power ranges from 10V to 60V.

The fan set 11 and the monitoring module 12 can be integrally formed as a single unit or separately formed as two units. Herein, when the fan set 11 and the monitoring module 12 are integrally formed as a single unit, they are disposed in the same housing. Otherwise, when the fan set 11 and the monitoring module 12 are separated formed as two units, the monitoring module 12 can be detached from the housing and is thus separated from the fan set 11.

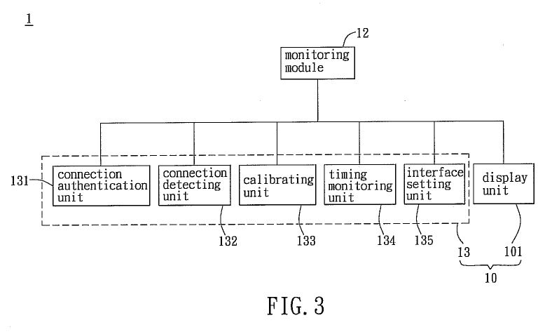

Referring to FIG. 3, the heat dissipating system 1 further includes an electronic device 10 electrically connected to the monitoring module 12. The electronic device 10 can be a computer or a network apparatus, for example.

The heat dissipating system 1 further includes a monitor connection module 13, which is disposed in the electronic device 10, for connecting the electronic device 10 to the monitoring module 12. The monitoring module 12 has an identification code, which can be an identification message of the monitoring module 12, or a password set by the user. The monitor connection module 13 has a connection authentication unit 131 for recognizing the identification code of the monitoring module 12 and thus judging whether the connection has been established or not. The monitor connection module 13 can firstly transmit a signal to the monitoring module 12, and then the monitoring module 12 transmits a responding signal containing the identification code according to the signal to establish the connection. The method of establishing the connection is only for the illustrative purpose without limiting the scope of the present invention. Thus, the user can control the monitoring module 12 through the electronic device 10.

The monitor connection module 13 further includes a connection detecting unit 132, a calibrating unit 133 and a timing monitoring unit 134. The connection detecting unit 132 detects a connection status between the monitoring module 12 and the monitor connection module 13. The calibrating unit 133 calibrates the measured value sensed by the sensing unit 121. The timing monitoring unit 134 timely generates a monitoring command and outputs the monitoring command to the monitoring module 12, and thus to control the fan set 11 via the monitoring module 12.

The electronic device 10 has a display unit 101 for demonstrating a user interface. When the user interface is operated, the monitoring command can be generated and transmitted to the monitoring module 12 so that the fan set 11 can be controlled through the monitoring module 12. The display unit 101 can be a touch panel, and the user interface can be a touch interface. The monitor connection module 13 further includes an interface setting unit 135. When the heat dissipating system 1 has a plurality of monitoring modules, the interface setting unit 135 can set different digit colors or digit background colors of all connected monitoring modules on the user interface to make the user easily observe and distinguish between the monitoring modules.

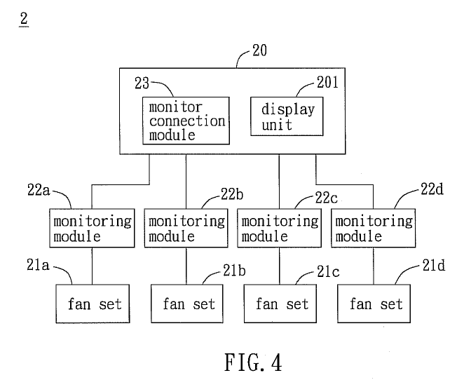

Referring to FIG. 4, a heat dissipating system 2 according to a third embodiment of the present invention includes a plurality of fan sets 21a to 21d and a plurality of monitoring modules 22a to 22d. The monitoring modules 22a to 22d respectively control rotation speeds of the fans of the fan sets 21a to 21d, and each of the monitoring modules 22a to 22d has an identification code. The elements and controlling methods of the fan sets 21a to 21d and the monitoring modules 22a to 22d according to this embodiment have been mentioned in the above embodiments, so the detailed descriptions thereof will be omitted.

The heat dissipating system 2 further includes an electronic device 20 electrically connected to the monitoring modules 22a to 22d. The electronic device 20 can be a computer or a network apparatus. The heat dissipating system 2 further includes a monitor connection module 23 disposed in the electronic device 20. The monitor connection module 23 can be connected to the monitoring modules 22a to 22d according to the identification codes of the monitoring modules 22a to 22d, respectively. Because the elements of the electronic device 20 and the monitor connection module 23 and the methods of connecting the monitor connection module 23 with the monitoring modules 22a to 22d have been described in the above-mentioned embodiment, the detailed descriptions thereof will be omitted. After the connections are established, the user can operate and individually control the monitoring modules 22a to 22d via a display unit 201 of the electronic device 20.

In summary, the heat dissipating system of the present invention can set the parameter values via the setting unit of the monitoring module, and control the rotation speeds of the fans through the controlling unit according to the parameter values and/or the measured value sensed by the sensing unit. For example, the rotation speed is increased when the temperature rises, and the rotation speed is decreased when the temperature falls so that the rotation speed can be intelligently adjusted in a multi-stage manner. In addition, when the heat dissipating system has many fan sets and monitoring modules, each monitoring module has an identification code to be identified so that the individual control can be achieved. Compared with the prior art, the present invention allows the user to set the parameter values so that the function of intelligently adjusting the rotation speed in the multi-stage manner can be achieved, the heat dissipating efficiency and the working performance can be enhanced, and the fan sets can be individually controlled.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A heat dissipating system, comprising:
a fan set having at least one fan; and
a monitoring module having at least one sensing unit, a controlling unit and a setting unit, wherein the setting unit sets a plurality of parameter values, and the controlling unit controls a rotation speed of the fan according to the parameter values and/or at least one measured value sensed by the sensing unit.

2. The heat dissipating system according to claim 1, wherein the sensing unit is a temperature sensor, a humidity sensor, a temperature-humidity sensor or a rotation speed sensor.

3. The heat dissipating system according to claim 1, wherein the sensing unit controls a plurality of fans of the fan set, or the number of the sensing units is equal to the number of the fans in the fan set.

4. The heat dissipating system according to claim 1, wherein the measured value or the parameter value comprises a temperature value, a humidity value, a temperature-humidity value or a rotation speed value.

5. The heat dissipating system according to claim 1, wherein the controlling unit determines the rotation speed according to a look-up-table or a calculation of a formula, the setting unit sets the parameter values by using an intelligent manner, or the parameter values are set by using up and down buttons instead of using digit buttons.

6. The heat dissipating system according to claim 1, wherein the monitoring module further comprises an operation interface having a display unit and a button unit so that a user sets each of the parameter values in the setting unit through an input of the button unit and a demonstration of the display unit.

7. The heat dissipating system according to claim 6, wherein the display unit demonstrates at least one information data comprising the measured value and/or the parameter values in a cyclic manner or by changing the unit of the information data.

8. The heat dissipating system according to claim 6, wherein when the monitoring module is enabled, the display unit demonstrates a starting status scenario.

9. The heat dissipating system according to claim 1, wherein the monitoring module further comprises a warning unit for outputting a warning signal when the measured value exceeds a preset value, the warning unit is a speaker or a buzzer, and the warning signal comprises a warning voice, a warning text, a warning image or a warning flash.

10. The heat dissipating system according to claim 1, wherein the controlling unit increases the rotation speeds of the other fans in the fan set when at least one of the fans in the fan set fails.

11. The heat dissipating system according to claim 1, wherein the monitoring module further comprises a power transforming unit for receiving an AC power input and transforming the AC power input into a DC power output, and the DC power ranges from 10V to 60V.

12. The heat dissipating system according to claim 1, wherein the fan set and the monitoring module are integrally formed as a single unit or separately formed as two units.

13. The heat dissipating system according to claim 1, further comprising an electronic device electrically connected with the monitoring module, and wherein the electronic device is a computer or a network apparatus.

14. The heat dissipating system according to claim 13, further comprising:
a monitor connection module disposed in the electronic device for connecting the electronic device with at least one monitoring module.

15. The heat dissipating system according to claim 14, wherein the monitor connection module comprises a connection authentication unit for recognizing an identification code of the monitoring module and thus judging whether the monitoring module is connected with the electronic device, and the identification code is an identification message of the monitoring module or a password set by a user.

16. The heat dissipating system according to claim 14, wherein the monitor connection module comprises a calibrating unit for calibrating the measured value sensed by the sensing unit, a connection detecting unit for detecting a connection status between the monitoring module and the monitor connection module, or a timing monitoring unit for timely generating a monitoring command and outputting the monitoring command to the corresponding monitoring module so that the monitoring module controls the fan set.

17. The heat dissipating system according to claim 13, wherein the electronic device has a display unit for demonstrating a user interface.

18. The heat dissipating system according to claim 17, wherein a monitoring command is generated when the user interface is operated, and the monitoring command is transmitted to the corresponding monitoring module so that the monitoring module controls the fan set.

19. The heat dissipating system according to claim 17, wherein the display unit is a touch panel, and the user interface is a touch interface, and the monitor connection module further comprises an interface setting unit for setting different digit colors or digit background colors of the monitoring module on the user interface.

20. A heat dissipating system, comprising:
a plurality of fan sets each comprising at least one fan; and
a plurality of monitoring modules for respectively controlling rotation speeds of the fans of the fan sets, wherein each of the monitoring modules has an identification code, at least one sensing unit, a controlling unit and a setting unit, the setting unit sets a plurality of parameter values, and the controlling unit controls the rotation speed of the corresponding fan set according to the parameter values and/or at least one measured value sensed by the sensing unit.
